(19) United States
(12) Patent Application Publication
(10) Pub. No.: US 2025/0133907 A1
(43) Pub. Date: Apr. 24, 2025

(54) DISPLAY PANEL AND MANUFACTURING METHOD THEREOF, DISPLAY DEVICE

(71) Applicant: GUANGZHOU CHINA STAR OPTOELECTRONICS SEMICONDUCTOR DISPLAY TECHNOLOGY CO., LTD., Guangzhou (CN)

(72) Inventors: Youyuan KUANG, Guangzhou (CN); Yan PENG, Guangzhou (CN)

(21) Appl. No.: 18/397,473

(22) Filed: Dec. 27, 2023

(30) Foreign Application Priority Data
Oct. 18, 2023 (CN) 202311355282.2

(51) Int. Cl. H10K 59/122; H10K 59/12; H10K 59/80

(52) U.S. Cl. CPC H10K 59/122; H10K 59/1201; H10K 59/80515

(57) ABSTRACT

A display panel includes an array substrate, an electrode layer, a pixel definition layer, and a light-emitting layer. The electrode layer includes a plurality of first electrodes connected to the array substrate. The pixel definition layer includes a plurality of first embankments surrounding to form a plurality of pixel openings which expose the plurality of first electrodes. The gap is disposed between one of the plurality of first embankments and one of the plurality of first electrode and is arranged around the first electrode. The light-emitting layer includes a plurality of light-emitting units that are correspondingly arranged within the plurality of pixel openings and cover the plurality of first electrodes and the gaps.

### CROSS REFERENCE TO RELATED APPLICATION

This application claims priority to Chinese Application No. 202311355282.2, filed on Oct. 18, 2023. The entire disclosures of the above applications are incorporated herein by reference.

### FIELD OF THE INVENTION

The present disclosure relates to the field of display technology, more particularly, to a display panel and a manufacturing method thereof, and a display device.

### BACKGROUND

Organic Light Emitting Diode (OLED) is currently an emerging mass production method for OLED. In printing OLED products, a printer is used for RGB pixel production. However, the printer head has varying control capabilities over ink droplets, and the production of TFT (Thin Film Transistor) backboards requires the production of a bank (embankment) functional layer. Due to the inverted trapezoidal structure of the bank, the film thickness at the edge of the pixel is often thinner than at the center, resulting in poor consistency in the thickness and morphology of the inner film of the pixel, causing inconsistent brightness or partial none mission of light within the pixel. This causes uneven brightness or inconsistent colors on the display panel.

### SUMMARY

One embodiment of the present disclosure is directed to a display panel aimed at overcoming the technical problem of thin film thickness at the edge position of pixels compared to the center position in the prior art, which leads to poor consistency in pixel inner film thickness and morphology, resulting in inconsistent brightness or partial non emission of light within pixels. Another embodiment of the present disclosure is directed to a method for manufacturing a display panel. One embodiment of the present disclosure is directed to a display device.

A display panel as described in one embodiment of the present disclosure comprises an array substrate, an electrode layer, a pixel definition layer, and a light-emitting layer. The electrode layer is arranged on the array substrate, and the electrode layer comprises a plurality of first electrodes connected to the array substrate. The pixel definition layer is set on the array substrate, which comprises a plurality of first embankments. The first embankments surround to form a plurality of pixel openings, and the pixel openings expose corresponding to the first electrodes. There is a gap disposed between the first embankment and the first electrode, and the gap is arranged around the first electrode. The light-emitting layer comprises a plurality of light-emitting units, which are correspondingly arranged within the pixel opening and cover the first electrode and the gap.

Optionally, the pixel definition layer further comprises a plurality of second embankments correspondingly disposed within the gaps and surround the plurality of first electrodes, and the plurality of light-emitting unit cover the plurality of second embankments.

Optionally, a material of the second embankment is a hydrophilic material.

Optionally, the array substrate has a thickness direction, the second embankment has a first height h along the thickness direction, and the first electrode has a second height H along the thickness direction, satisfying: h≤H.

Optionally, a thickness direction and a width direction of the array substrate are perpendicular, and a pitch d of the gap along the width direction satisfies: 1 μm≤d≤10 μm.

Optionally, a width D of the first embankment along the width direction satisfies: 0.1≤d/D≤0.5.

Optionally, a material of the first embankment is a drainage material.

Correspondingly, a method for manufacturing a display panel according to one embodiment of the present disclosure comprises: providing a plurality of array substrates; forming an electrode layer on the array substrate, the electrode layer comprises a plurality of first electrodes, and the first electrode is connected to the array substrate; forming a first pixel definition layer on the array substrate, the first pixel definition layer comprises a plurality of first embankments, the first embankments surround the formed pixel openings, and the pixel openings expose the corresponding first electrode, and there is a gap disposed between the first electrode and the first embankment, and the gap is arranged around the first electrode; forming a light-emitting layer, the light-emitting layer comprises a plurality of light-emitting units, wherein the light-emitting units are correspondingly arranged within the pixel opening and cover the first electrode and the gap.

Optionally, the light-emitting layer is formed by printing.

Correspondingly, a display device as described in another embodiment of the present disclosure comprises a display panel. The display panel includes an array substrate, an electrode layer, a pixel definition layer, and a light-emitting layer. The electrode layer is arranged on the array substrate, and the electrode layer comprises a plurality of first electrodes connected to the array substrate. The pixel definition layer is set on the array substrate, which comprises a plurality of first embankments. The first embankments surround to form a plurality of pixel openings, and the pixel openings expose corresponding to the first electrodes. There is a gap disposed between the first embankment and the first electrode, and the gap is arranged around the first electrode. The light-emitting layer comprises a plurality of light-emitting units, which are correspondingly arranged within the pixel opening and cover the first electrode and the gap.

Optionally, the pixel definition layer further comprises a plurality of second embankments correspondingly disposed within the gaps and surround the plurality of first electrodes, and the plurality of light-emitting unit cover the plurality of second embankments.

Optionally, a material of the second embankment is a hydrophilic material.

Optionally, the array substrate has a thickness direction, the second embankment has a first height h along the thickness direction, and the first electrode has a second height H along the thickness direction, satisfying: h≤H.

Optionally, a thickness direction and a width direction of the array substrate are perpendicular, and a pitch d of the gap along the width direction satisfies: 1 μm≤d≤10 μm.

Optionally, a width D of the first embankment along the width direction satisfies: 0.1≤d/D≤0.5.

Optionally, a material of the first embankment is a drainage material.

In contrast to prior art, the display panel according to one embodiment of the present disclosure comprises an array substrate, an electrode layer, a pixel definition layer, and a light-emitting layer. The electrode layer is arranged on the array substrate, and the electrode layer comprises a plurality of first electrodes connected to the array substrate. The pixel definition layer is set on the array substrate, which comprises a plurality of first embankments. The first embankments surround to form a plurality of pixel openings, and the pixel openings expose corresponding to the first electrodes. There is a gap disposed between the first embankment and the first electrode, and the gap is arranged around the first electrode. The light-emitting layer comprises a plurality of light-emitting units, which are correspondingly arranged within the pixel opening and cover the first electrode and the gap. The pixel definition layer of the display panel is equipped with a first embankment to enclose a pixel opening, the first electrode of the electrode layer is correspondingly set within the pixel opening, and a gap surrounding the first electrode is formed with the first embankment interval, and the light-emitting unit of the luminous layer is correspondingly set within the pixel opening, covering the first electrode and gap, so that the uneven thickness area of the light-emitting unit near the edge of the pixel opening can fall within the gap, a portion covering the first electrode is a central area with a more uniform thickness, so that the emitting unit can maintain good film thickness consistency and morphology consistency in the emitting area of the first electrode, thereby ensuring the consistency of emitting brightness and color.

In contrast to prior art, a method for manufacturing a display panel according to one embodiment of the present disclosure comprises: providing a plurality of array substrates; forming an electrode layer on the array substrate, the electrode layer comprises a plurality of first electrodes, and the first electrode is connected to the array substrate; forming a first pixel definition layer on the array substrate, the first pixel definition layer comprises a plurality of first embankments, the first embankments surround the formed pixel openings, and the pixel openings expose the corresponding first electrode, and there is a gap disposed between the first electrode and the first embankment, and the gap is arranged around the first electrode; forming a light-emitting layer, the light-emitting layer comprises a plurality of light-emitting units, wherein the light-emitting units are correspondingly arranged within the pixel opening and cover the first electrode and the gap. The manufacturing method can manufacture a display panel including the above structure and the above beneficial effects, which will not be described again.

In contrast to prior art, the display device according to one embodiment of the present disclosure includes the above-mentioned display panel, or includes a display panel manufactured by the above-mentioned manufacturing method. Therefore, the display device can have all the technical features and beneficial effects of the above-mentioned display panel or the above-mentioned manufacturing method, which will not be described again.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a schematic diagram of a local layered structure of a display panel in the first embodiment according to the present disclosure.

FIG. 2 is a schematic diagram of the local layered structure of the display panel in the second embodiment according to the present disclosure.

FIG. 3 is a flowchart of a method for manufacturing a display panel according to one embodiment of the present disclosure.

FIG. 4 is a top view of a first state of the display panel in a manufacturing process according to the first embodiment of the present disclosure.

FIG. 5 is a schematic diagram of the layered structure of the first state of the display panel in the manufacturing process of the first embodiment according to the present disclosure.

FIG. 6 is a schematic diagram of the layered structure of the second state of the display panel in the first embodiment according to the present disclosure during the manufacturing process.

FIG. 7 is a schematic diagram of the layered structure of the first state of the display panel in the second embodiment according to the present disclosure during the manufacturing process.

FIG. 8 is a schematic diagram of the layered structure of the second state of the display panel in the second embodiment according to the present disclosure during the manufacturing process.

FIG. 9 is a schematic diagram of a film thickness distribution of a light-emitting unit in the display panel according to the present disclosure.

FIG. 10 is a schematic diagram of the printing principle.

### DESCRIPTION OF THE EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

The following disclosure provides many different embodiments or examples to implement different structures of the present disclosure. In order to simplify the disclosure of the present disclosure, the components and settings of specific examples are described below. They are for example purposes only and are not intended to limit this application. Further, the present disclosure may repeat reference numbers and/or reference letters in different examples, such duplication is for the purpose of simplification and clarity, and does not by itself indicate the relationship between the various embodiments and/or settings discussed. Further, the present disclosure provides various examples of specific processes and materials, but those of ordinary skill in the art may be aware of the application of other processes and/or the use of other materials. The following are described in detail, it should be noted that the order of description of the following embodiments is not used as a qualification for the preferred order of embodiments.

In the description of this application, it should be understood that the orientation or positional relationship indicated by the terms “thickness”, “width”, “upper”, “lower”, “inner”, “outer”, etc. are based on those shown in the accompanying drawings. The orientation or positional relationship is only for the convenience of describing the present disclosure and simplifying the description, and does not indicate or imply that the device or element referred to must have a specific orientation, be constructed and operated in a specific orientation, and therefore cannot be understood as a limitation of the present disclosure. In the description of this application, “plurality” means two or more, and at least one means one, two, or more than two, unless otherwise clearly and specifically limited. The term “layer” as used in this application refers to a portion of material that includes a region of thickness. A layer may extend over the entire underlying or superstructure, or may extend over a localized extent of the underlying or superstructure. Furthermore, a layer may be a region of a homogeneous or inhomogeneous continuous structure, the thickness of which is less than the thickness of the continuous structure. For example, a layer may be located between the top and bottom surfaces of a continuous structure or between any pair of horizontal planes therebetween. The layers may extend horizontally, vertically and/or along tapered surfaces. A layer may include multiple sub-layers, for example, a semiconductor layer may include one or more doped or undoped semiconductor layers, and may be of the same or different materials.

It should also be noted that in the drawings of the specification of this application, the arrow marked X is used to indicate the width direction, and the arrow marked Y is used to indicate the thickness direction. The width direction X and the thickness direction Y are introduced to clearly describe the structure of the display panel of the embodiment of the present disclosure. The thickness direction Y of the array substrate 10 is the direction corresponding to the thickness dimension of the array substrate 10 in a normal display panel, and the width direction X is a direction perpendicular to each other with the thickness direction Y as a reference direction.

In response to the technical problem of thin film thickness at the edge position of pixels compared to the center position in existing display panels, which leads to poor consistency in pixel inner film thickness and morphology, resulting in inconsistent brightness or partial non emission of light within pixels, the present embodiment provides a display panel, which can be an OLED display panel.

Please refer to FIGS. 1 and 4. In the first embodiment of the present disclosure, the display panel comprises an array substrate 10, a pixel definition layer 20, an electrode layer 30, and a light-emitting layer 40. The electrode layer 30 is arranged on the array substrate 10, and the electrode layer comprises a plurality of first electrodes 31 connected to the array substrate 10. The pixel definition layer 20 is set on the array substrate 10, which comprises a plurality of first embankments 21. The first embankment 21 forms a pixel opening 22 around it, and the pixel opening 22 exposes the corresponding first electrode 31. There is a gap of 50 disposed between the first embankment 21 and the first electrode 31, which is set around the first electrode 31. The light-emitting layer 40 comprises a plurality of light-emitting units 41, which are correspondingly arranged within the pixel opening 22 and cover the first electrode 31 and the gap 50.

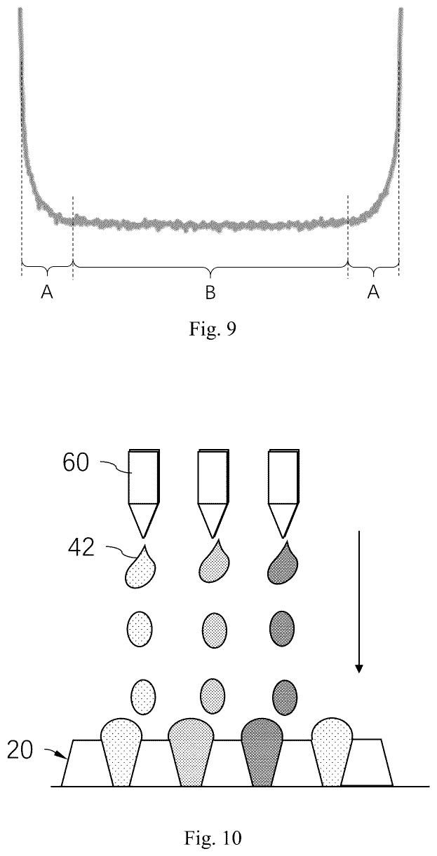

Please refer to FIG. 9. An uneven thickness area A of the emitting unit 41 near the edge of the pixel opening 22 (i.e. an inner wall of the first embankment 21) can fall within the gap 50, while a portion covering the first electrode 31 is the center area B with a more uniform thickness. A portion of the emitting unit 41 covering the first electrode 31 is its emitting area, which overlaps with the center area B mentioned above. That is to say, the emitting unit 41 corresponds to the emitting area of the first electrode 31, which can maintain good film thickness consistency and morphology consistency, thereby ensuring the consistency of emitting brightness and color, and improving the display effect of the display panel.

Specifically, the array substrate 10 belongs to the key component of the display panel of the present embodiment, which carries the pixel array of the display panel (i.e. the array composed of the light-emitting units 41). Moreover, it also comprises a circuit driver (not shown in the figures) for controlling the brightness and color of each pixel (corresponding to the light-emitting unit 41) in the pixel array. The array substrate 10 can convert the input electrical signal into the required current or voltage for each pixel through its circuit driver, to activate the corresponding light-emitting unit 41 for each pixel to emit light. By precisely controlling the circuit driver, high-quality image display and color accuracy can be achieved.

The pixel definition layer 20 is used to limit the number and shape of pixels carried in the pixel array on the array substrate 10. Through the pixel opening 22 formed by the first embankment 21, it can specifically define the area where each pixel is located, and the light-emitting unit 41 is correspondingly set inside the pixel opening 22.

The electrode layer 30 is set on the array substrate 10 and can be electrically connected to the corresponding light-emitting unit 41 and the circuit driver in the array substrate 10 through its first electrode 31 to control the light-emitting unit to emit light. In some embodiments, a second electrode (not shown in the figures) can also be provided above the light-emitting unit 41, with the first electrode 31 as the anode and the second electrode as the cathode, to enable the light-emitting unit 41 to emit light through the joint action of the anode and cathode. It should be understood that the specific polarity of the first electrode 31 can be designed according to needs, and there is no special limitation here.

The gap 50 is formed by the first electrode 31 and the first embankment 21 being spaced apart from each other, and the gap 50 is set around the first electrode 31. That is to say, the first electrode 31 is located in the middle area of the pixel opening 22 formed around the first embankment 21, and the gap 50 surrounds the outer circumference of the first electrode 31. Thus, when the light-emitting unit 41 is formed within the pixel opening 22, it can cover the first electrode 31 and the gap 50, and an uneven edge thickness area of the light-emitting unit 41 can fall within the gap 50, thereby ensuring that the pixel light-emitting area corresponding to the first electrode 31 has a relatively consistent film layer thickness, ensuring the consistency of display brightness and color.

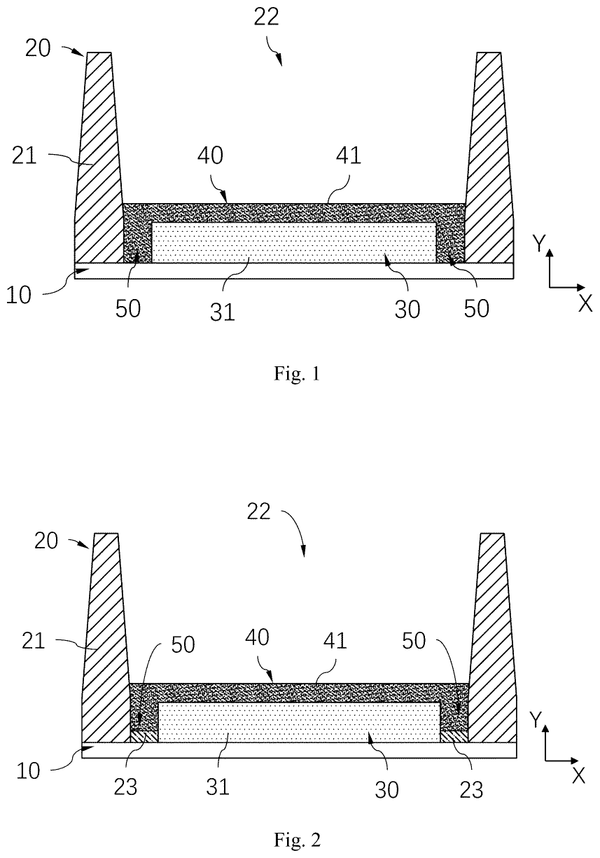

Please refer to FIG. 2. A structural difference disposed between the second embodiment and the first embodiment of this application is that the pixel definition layer 20 of the second embodiment further comprises a plurality of second embankments 23, which are correspondingly set within the gap 50 and surround the first electrode 31. The light-emitting unit 41 covers the second embankment 23. By setting a second embankment 23 within the gap 50, the uneven thickness area of the edge of the light-emitting unit 41 can be raised, which to some extent expands the range of the uniform thickness area of the light-emitting unit 41, further improves the consistency of display brightness and color, and enhances the display effect.

Furthermore, a material of the second embankment 23 is hydrophilic.

Hydrophilic materials have hydrophilic properties and can attract and adsorb surrounding liquid molecules, forming a uniform liquid film layer. This makes it easier for ink 42 to flow into the pixel opening 22, and makes the edge thickness of the light-emitting unit 41 more uniform during the film forming process, which can further expand the range of the uniform thickness area, ensure a more uniform thickness of the film layer area corresponding to the first electrode 31, and promote the improvement of the display effect.

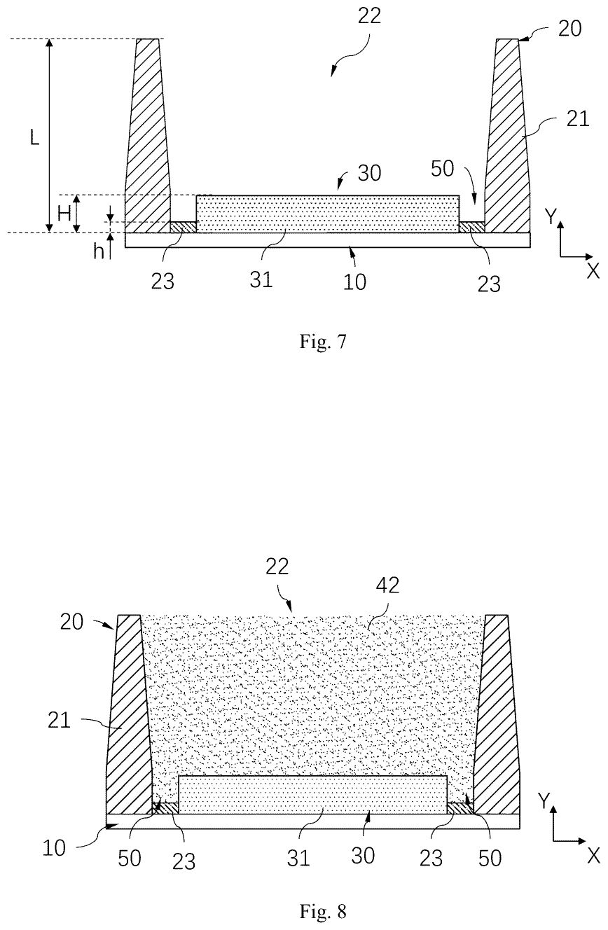

Please refer to FIG. 7. The second embankment 23 has a first height h along the thickness direction Y, and the first electrode 31 has a second height H along the thickness direction Y, satisfying the following conditions: h≤H. Due to the lower height of the second embankment 23 compared to the top surface of the first electrode 31, ink 42 has a more uniform thickness in the area corresponding to the first electrode 31 during the drying process, which can further improve the quality of the display panel and enhance the display effect.

Furthermore, the first embankment 21 has a fifth dimension L along the thickness direction Y, which satisfies L>H, thus facilitating the flow of ink 42 into the pixel opening 22 to form a suitable thickness of luminescent unit 41 on one hand, and on the other hand, it can meet the requirements of the display panel for the viewing angle of light. Specifically, L ranges 1-2 μm. For example, it can be 1 μm, 1.1 μm, 1.2 μm, 1.3 μm, 1.4 μm, 1.5 μm, 1.6 μm, 1.7 μm, 1.8 μm, 1.9 μm, and 2 μm, or any value between any two above-mentioned values. H can be disposed between 15 and 75 nm, for example, it can be any value in the range of 15 nm, 20 nm, 25 nm, 30 nm, 35 nm, 40 nm, 45 nm, 50 nm, 55 nm, 60 nm, 65 nm, 70 nm, 75 nm, or any value between any two above-mentioned values.

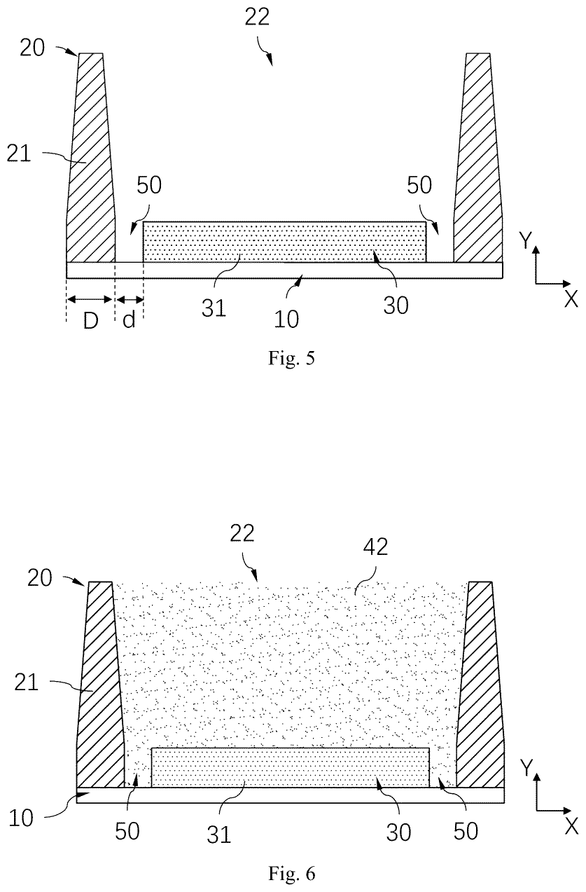

Please refer to FIG. 5, gap 50 has a pitch d along the width direction X, which meets the requirements. one μM≤d≤10 μM. For example, d can be 1 μm, 2 μm, 3 μm, 4 μm, 5 μm, 6 μm, 7 μm, 8 μm, 9 μm, and 10 μm, or any value between any two above-mentioned values. Within this range, the larger the pitch d is, the wider the gap 50 is, and the more emitting units 41 fall into the uneven edge thickness area within the gap 50. Correspondingly, the more uniform the film thickness of the emitting units 41 falls into the corresponding area of the first electrode 31, the more effective the display effect is.

Furthermore, the first embankment 21 has a width D along the width direction X, which satisfies: 0.1≤d/D≤0.5. For example, d/D can be any value in the range of 0.1, 0.2, 0.3, 0.4, 0.5, or disposed between any two values. On the one hand, while keeping the pixel emitting area unchanged, due to the presence of gap 50, the first embankment 21 is narrowed. Limiting the ratio of the pitch d to the width D within this range can ensure that the uneven edge thickness area of the emitting unit 41 almost completely falls within the gap 50, ensuring the display effect. On the other hand, it can avoid the first embankment 21 being too narrow, which weakens the barrier effect on ink 42 and leads to ink mixing disposed between adjacent pixels, thereby avoiding the occurrence of adjacent pixel color mixing.

Furthermore, the material of the first embankment 21 is a drainage material. Specifically, it can be a hydrophobic photoresist material, and there are no specific limitations on the specific material. Therefore, after entering the pixel opening 22, ink 42 can cover more gaps 50 and the first electrode 31, ensuring the thickness of the film layer and improving the uniformity of the film layer.

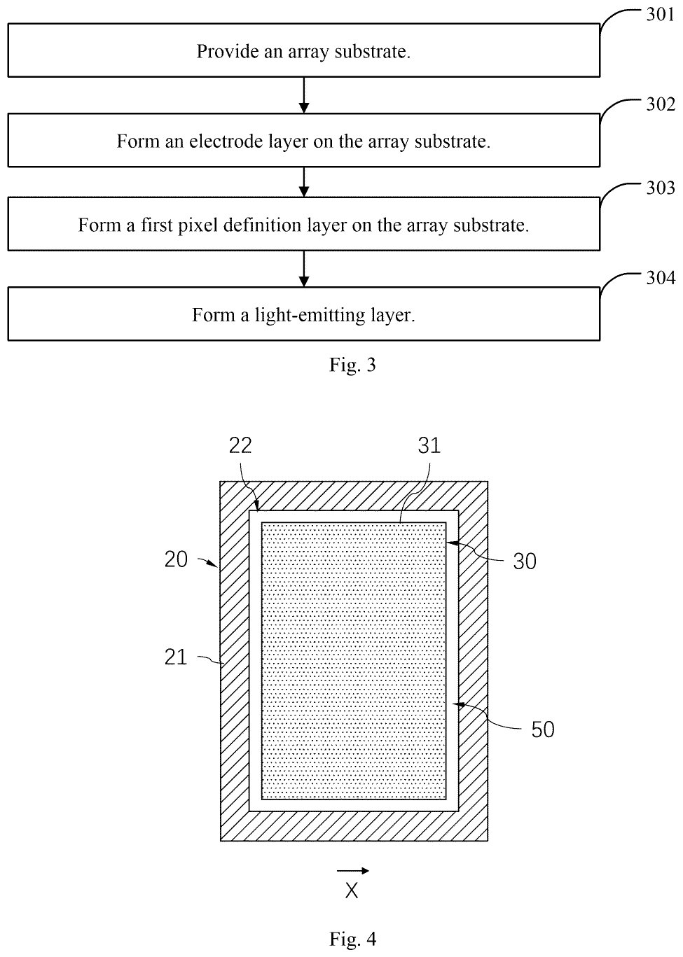

Correspondingly, the present embodiment also provides a method of manufacturing a display panel. Please refer to FIG. 3, the method includes blocks 301-304.

At block 301, an array substrate 10 is provided.

At block 302, an electrode layer 30 is formed on the array substrate 10. The electrode layer 30 comprises a plurality of first electrodes 31, and the first electrode 31 is connected to the array substrate 10.

At block 303, a first pixel definition layer 20 is formed on the array substrate 10. The first pixel definition layer 20 includes a plurality of first embankments 21. The first embankment 21 forms a pixel opening 22 around it, and the pixel opening 22 exposes the corresponding first electrode 31. There is a gap of 50 disposed between the first electrode 31 and the first embankment 21, which is arranged around the first electrode 31.

At block 304, a light-emitting layer 40 is formed. The light-emitting layer 40 comprises a plurality of light-emitting units 41 corresponding to the pixel opening 22 and covering the first electrode 31 and the gap 50.

By using the above manufacturing method, a display panel with the above structure can be prepared, ensuring the consistency of the film thickness in the emitting area of the emitting unit 41 of the display panel, thereby ensuring the consistency of display brightness and color.

Please combine FIGS. 5, 6, 7, 8, and 10 together, and in some embodiments, form a light-emitting layer 40 by printing. Specifically, ink 42 can be printed into the corresponding pixel opening 22 through the printing nozzle 60. After the ink 42 dries, the display panel shown in FIGS. 1 and 2 can be formed.

Correspondingly, a display device as described in another embodiment of the present disclosure comprises a display panel. The display panel includes the above-mentioned display panel, or includes a display panel manufactured by the above-mentioned manufacturing method. The display device can be a mobile phone, a laptop, a television, a monitor, etc.

In the above embodiments, each embodiment is described with its own emphasis. For parts that are not described in detail in a certain embodiment, please refer to the relevant descriptions of other embodiments.

The display panel, its preparation method, and the display device provided by the embodiments of the present disclosure have been introduced in detail, and specific examples have been used to illustrate the principles and implementation methods of the present disclosure. The description of the above embodiments is only used to help understand the present disclosure. The technical solution and its core idea of the application. One of ordinary skill in the art should understand that they can still modify the technical solutions recorded in the foregoing embodiments, or make equivalent substitutions for some of the technical features. These modifications or substitutions does not cause the essence of the corresponding technical solution to depart from the scope of the technical solution of each embodiment of the present disclosure.

What is claimed is:

1. A display panel, comprising:
an array substrate;
an electrode layer on the array substrate, comprising a plurality of first electrodes connected to the array substrate;
a pixel definition layer on the array substrate, comprising a plurality of first embankments surrounding to form a plurality of pixel openings which expose the plurality of first electrodes, and a gap is disposed between one of the plurality of first embankments and one of the plurality of first electrode and is arranged around the first electrode;
a light-emitting layer, comprising a plurality of light-emitting units that are correspondingly arranged within the plurality of pixel openings and cover the plurality of first electrodes and the gaps.

2. The display panel as claimed in claim 1, wherein the pixel definition layer further comprises a plurality of second embankments correspondingly disposed within the gaps and surround the plurality of first electrodes, and the plurality of light-emitting unit cover the plurality of second embankments.

3. The display panel as claimed in claim 2, wherein a material of the second embankment is a hydrophilic material.

4. The display panel as claimed in claim 2, wherein the array substrate has a thickness direction, the second embankment has a first height h along the thickness direction, and the first electrode has a second height H along the thickness direction, satisfying: h≤H.

5. The display panel as claimed in claim 1, wherein a thickness direction and a width direction of the array substrate are perpendicular, and a pitch d of the gap along the width direction satisfies: 1 μm≤d≤10 μm.

6. The display panel as claimed in claim 5, wherein a width D of the first embankment along the width direction satisfies: 0.1≤d/D≤0.5.

7. The display panel as claimed in claim 1, wherein a material of the first embankment is a drainage material.

8. A method for manufacturing a display panel, comprising:
providing an array substrate;
forming an electrode layer on the array substrate, wherein the electrode layer comprises a plurality of first electrodes, and the first electrode is connected to the array substrate;
forming a first pixel definition layer on the array substrate, wherein the first pixel definition layer comprises a plurality of first embankments surrounding to form pixel openings which expose the plurality of first electrodes, and a gap is disposed between the first embankment and the first electrode and is arranged around the first electrode;
forming a light-emitting layer comprising a plurality of light-emitting units that are correspondingly arranged within the plurality of pixel openings and cover the first electrode and the gap.

9. The method according to claim 8, wherein the light-emitting layer is formed by printing.

10. A display device, comprising a display panel, the display panel comprising:
an array substrate;
an electrode layer on the array substrate, comprising a plurality of first electrodes connected to the array substrate;
a pixel definition layer on the array substrate, comprising a plurality of first embankments surrounding to form a plurality of pixel openings which expose the plurality of first electrodes, and a gap is disposed between one of the plurality of first embankments and one of the plurality of first electrode and is arranged around the first electrode;
a light-emitting layer, comprising a plurality of light-emitting units that are correspondingly arranged within the plurality of pixel openings and cover the plurality of first electrodes and the gaps.

11. The display device as claimed in claim 10, wherein the pixel definition layer further comprises a plurality of second embankments correspondingly disposed within the gaps and surround the plurality of first electrodes, and the plurality of light-emitting unit cover the plurality of second embankments.

12. The display device as claimed in claim 11, wherein a material of the second embankment is a hydrophilic material.

13. The display device as claimed in claim 11, wherein the array substrate has a thickness direction, the second embankment has a first height h along the thickness direction, and the first electrode has a second height H along the thickness direction, satisfying: h≤H.

14. The display device as claimed in claim 10, wherein a thickness direction and a width direction of the array substrate are perpendicular, and a pitch d of the gap along the width direction satisfies: 1 μm≤d≤10 μm.

15. The display device as claimed in claim 5, wherein a width D of the first embankment along the width direction satisfies: 0.1≤d/D≤0.5.

16. The display device as claimed in claim 10, wherein a material of the first embankment is a drainage material.
